(19) United States
(12) Patent Application Publication
(10) Pub. No.: US 2026/0180543 A1
(43) Pub. Date: Jun. 25, 2026

(54) RAISED ELECTRODES IN PIEZOELECTRIC DEVICES

(71) Applicant: RF360 Singapore Pte. Ltd., Singapore (SG)

(72) Inventors: Ren Bin YANG, Singapore (SG); Philipp Michael JAEGER, Vaterstetten (DE); Marc Konstantin DIETRICH, Munich (DE); Nicolas RAAB, München (DE); Tomasz JEWULA, Markt Schwaben (DE)

(21) Appl. No.: 18/991,080

(22) Filed: Dec. 20, 2024

(51) Int. Cl. H03H 9/02; H03H 3/08; H03H 9/13; H03H 9/145

(52) U.S. Cl. CPC H03H 9/02574; H03H 3/08; H03H 9/02275; H03H 9/132; H03H 9/14541

(57) ABSTRACT

Aspects of the disclosure relate to an apparatus. The apparatus can include a piezoelectric layer including a surface along a surface plane. A plurality of piezoelectric structures extend from the surface in a direction orthogonal to the surface plane. The apparatus can include an electrode layer comprising an electrode disposed on the plurality of piezoelectric structures. wherein the electrode extends along an axis parallel to the surface plane to form at least one finger of an interdigitated transducer (IDT). In some cases, a surface acoustic wave (SAW) filter includes the IDT.

### TECHNICAL FIELD

This disclosure relates generally to acoustic transducers, and more specifically to piezoelectric microelectromechanical systems (MEMS) devices and fabrication of piezoelectric MEMS devices to improve performance.

### BACKGROUND

Micro-electro-mechanical system (MEMS) devices can be used in a variety of contexts. Piezoelectric MEMS devices, for example, can be used as transducers for converting mechanical stress into electrical signals. Electroacoustic resonators such as surface acoustic wave (SAW) and bulk acoustic wave (BAW) resonators are an example of such piezoelectric MEMS devices. MEMS acoustic transducer/sensors that convert acoustic energy into electrical signals, and/or converts an electrical signal into acoustic energy are another example of such MEMS devices.

Manufacturers of MEMS devices have taken a variety of approaches to improve device performance.

### SUMMARY

Aspects of the present disclosure describe microelectromechanical system (MEMS) devices, systems, and methods where raised electrodes are used in piezoelectric (PZ) devices to improve device performance. According to at least one illustrative example, a method is provided. The method includes: disposing an electrode structure on a surface plane of a piezoelectric layer, wherein the electrode structure comprises a plurality of fingers of an interdigitated transducer (IDT); and forming protrusions on the piezoelectric layer extending in a direction orthogonal to the surface plane to form a plurality of piezoelectric structures.

In another example, an apparatus is provided. The apparatus includes: a piezoelectric layer comprising a surface along a surface plane, wherein a plurality of piezoelectric structures extend from the surface in a direction orthogonal to the surface plane; and an electrode layer comprising an electrode disposed on the plurality of piezoelectric structures, wherein the electrode extends along an axis parallel to the surface plane to form at least one finger of an interdigitated transducer (IDT)

In another example, a non-transitory computer-readable medium is provided that has stored thereon instructions that, when executed by one or more processors, cause the one or more processors to: dispose an electrode structure on a surface plane of a piezoelectric layer, wherein the electrode structure comprises a plurality of fingers of an interdigitated transducer (IDT); and forming protrusions on the piezoelectric layer extending in a direction orthogonal to the surface plane to form a plurality of piezoelectric structures.

In accordance with another embodiment of the present disclosure, an apparatus is provided. The apparatus includes: means for disposing an electrode structure on a surface plane of a piezoelectric layer, wherein the electrode structure comprises a plurality of fingers of an interdigitated transducer (IDT); and means for forming protrusions on the piezoelectric layer extending in a direction orthogonal to the surface plane to form a plurality of piezoelectric structures.

### BRIEF DESCRIPTION OF DRAWINGS

FIG. 1 illustrates an example operating environment for a micro-acoustic filter with raised electrodes, in accordance with aspects described herein.

FIG. 2 illustrates an example wireless transceiver including surface acoustic wave (SAW) filters with raised electrodes, in accordance with aspects described herein.

FIG. 3A illustrates an example implementation of a SAW filter that can be implemented with raised electrodes, in accordance with aspects described herein.

FIG. 3B illustrates a two dimensional (2D) cross section view of the example implementation of the portion of the SAW filter of FIG. 3A, in accordance with aspects described herein.

FIG. 4A illustrates an example implementation of a portion of temperature compensation SAW (TC-SAW) filter, in accordance with aspects described herein.

FIG. 4B illustrates a 2D cross section view of the portion of the TC-SAW filter of FIG. 4A, in accordance with aspects described herein.

FIG. 5A illustrates an example implementation of portion of a SAW filter, in accordance with aspects described herein.

FIG. 5B illustrates a 2D cross section view of the portion of the SAW filter of FIG. 5A, in accordance with aspects described herein.

FIG. 5C illustrates an additional 2D cross section view of the portion of the SAW filter of FIG. 5A with raised electrodes, in accordance with aspects described herein.

FIG. 5D illustrates an additional 2D cross section view of the portion of the SAW filter of FIG. 5A with raised electrodes, in accordance with aspects described herein.

FIG. 6A illustrates an example plot of mechanical stress for a 2D cross section of an electrode included in a piezoelectric device without raised electrodes, in accordance with aspects described herein.

FIG. 6B illustrates an example plot of mechanical stress for a 2D cross section of an electrode included in a piezoelectric device with raised electrodes, in accordance with aspects described herein.

FIG. 7 illustrates simulated performance of TC-SAW filters without raised electrodes and with raised electrodes, in accordance with aspects described herein.

FIG. 8 illustrates a method associated with a piezoelectric device with raised electrodes, in accordance with aspects described herein.

FIG. 9 is a block diagram of a computing device that can be used with aspects described herein.

Like reference symbols in the various drawings indicate like elements.

### DETAILED DESCRIPTION

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

To transmit or receive radio-frequency (RF) signals within a given frequency band, an electronic device may use filters to pass signals within the frequency band and to suppress (e.g., attenuate) jammers or noise having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material as a vibrating medium, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electrical and acoustic waves.

The acoustic wave propagates across the piezoelectric material at a velocity having a magnitude that is significantly less than that of the propagation velocity of the electrical wave. Generally, the magnitude of the propagation velocity of a wave is proportional to a size of a wavelength of the wave. Consequently, after conversion of the electrical signal wave into the acoustic wave, the wavelength of the acoustic wave is significantly smaller than the wavelength of the electrical signal wave. The resulting smaller wavelength of the acoustic wave enables filtering to be performed using a smaller filter device. This permits acoustic filters to be used in space-constrained devices, including portable electronic devices such as cellular phones.

Piezoelectric devices operate using the piezoelectric effect, where mechanical displacement in a piezoelectric material generates an electrical response. Such devices can operate as transducers for sound waves as well as high frequency resonators.

Design of acoustic filters that can provide filtering for high-frequency applications while maintaining target performance levels can involve trade-offs and challenges. For example, the performance of a piezoelectric device can be characterized by thermal coefficient of frequency (TCF), pole-zero distance (PZD), static capacitance (C₀), power durability, and/or electromechanical coupling coefficient (k²), among others. Power durability requirements for piezoelectric devices can increase due to higher power densities. In some cases, metallic structures (e.g., electrodes) may be subjected to heating and mechanical stresses that will lead to irreversible deformities. In one illustrative example, deformities in metallic structures in a resonator (e.g., a surface acoustic wave (SAW)) filter can result in unwanted frequency shifts in the filter pass band and eventual failure.

In some cases, piezoelectric devices may have PZD and/or k² values that are higher than required for a particular application. In some implementations, the PZD and/or k² can be lowered by the application of capacitors in parallel with the piezoelectric device. In some cases, an increase in TCF and/or power durability may improve the performance of certain piezoelectric devices, such as a temperature compensated surface acoustic wave (TC-SAW) filter.

Systems and techniques are needed for manufacturing piezoelectric devices with increased TCF and power durability. In one illustrative example, a TC-SAW filter with an increased TCF may provide a more consistent frequency response with temperature variation. In another illustrative example, a piezoelectric device with increased power durability may have an increased operational life.

Systems, apparatuses, and processes (also referred to as methods), and computer-readable media (collectively referred to as “systems and techniques”) are described herein for piezoelectric devices with raised electrodes. In some cases, the systems and techniques described herein may increase the TCF and/or power handling capability of a piezoelectric device. In addition, the systems and techniques described herein may reduce the amount of parallel capacitance required to reduce the PZD and/or k² of a piezoelectric device.

Additional details associated with such device structures and improved device performance are provided below with respect to the figures.

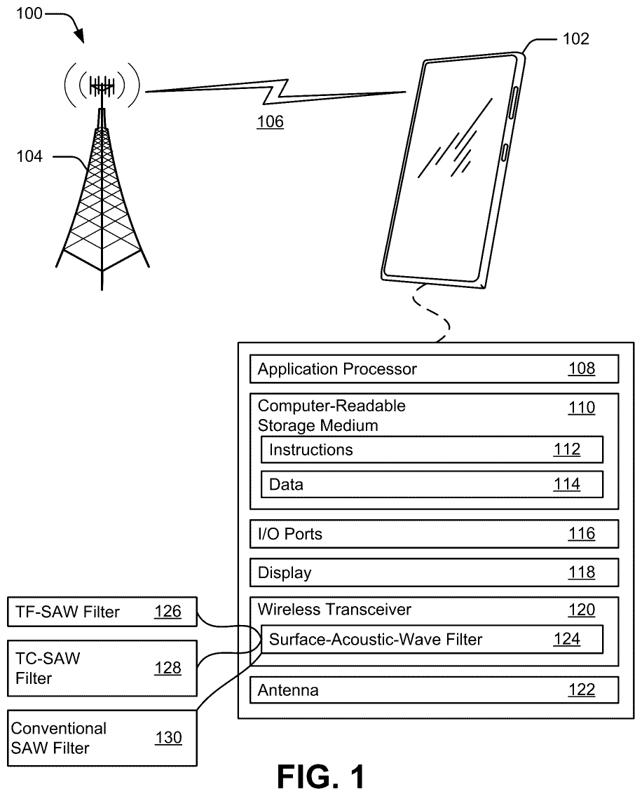

FIG. 1 illustrates an example environment 100 for a piezoelectric device. In the environment 100, a computing device 102 communicates with a base station 104 through a wireless communication link 106 (e.g., a wireless link). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), or 5th-generation (5G) cellular; IEEE 902.11 (e.g., Wi-Fi®); IEEE 902.15 (e.g., Bluetooth®); IEEE 902.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium (CRM) 110. The application processor 108 can include any type of processor, such as a multi-core processor, which executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one SAW filter 124. In some implementations, the wireless transceiver 120 includes multiple SAW filters 124, which can be arranged in series, in parallel, in a ladder structure, in a lattice structure, or some combination thereof. In some implementations, the SAW filter 124 can be a thin-film SAW (TF-SAW) filter 126, a TC-SAW filter 128, or a conventional SAW filter 130. The SAW filter 124 can include raised electrodes for improving power handling performance.

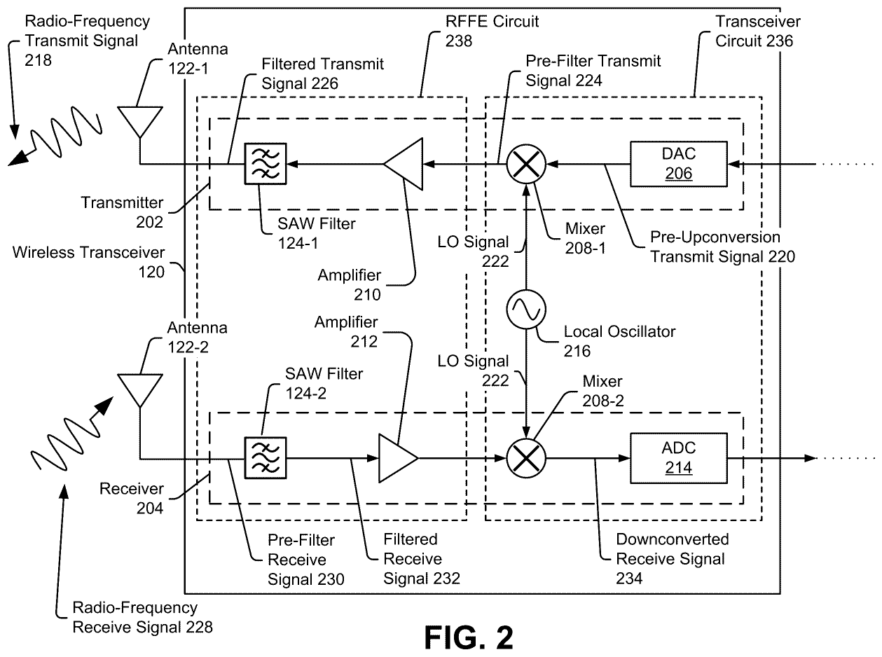

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown), such as a transmit-receive switch or a circulator. The transmitter 202 is shown to include at least one digital-to-analog converter (DAC) 206, at least one first mixer 208-1, at least one amplifier 210 (e.g., a power amplifier), and at least one first SAW filter 124-1. The receiver 204 includes at least one second SAW filter 124-2, at least one amplifier 212 (e.g., a low-noise amplifier), at least one second mixer 208-2, and at least one analog-to-digital converter (ADC) 214. The first mixer 208-1 and the second mixer 208-2 are coupled to a local oscillator 216. Although not explicitly shown, the DAC 206 of the transmitter 202 and the ADC 214 of the receiver 204 can be coupled to the application processor 108 (of FIG. 1) or another processor associated with the wireless transceiver 120 (e.g., a modem).

In some implementations, the wireless transceiver 120 is implemented using multiple circuits, such as a transceiver circuit 236 and a RF front-end (RFFE) circuit 238. As such, the components that form the transmitter 202 and the receiver 204 are distributed across these circuits. As shown in FIG. 2, the transceiver circuit 236 includes the DAC 206 of the transmitter 202, the mixer 208-1 of the transmitter 202, the mixer 208-2 of the receiver 204, and the ADC 214 of the receiver 204. In other implementations, the DAC 206 and the ADC 214 can be implemented on another separate circuit that includes the application processor 108 or the modem. The RFFE circuit 238 includes the amplifier 210 of the transmitter 202, the SAW filter 124-1 of the transmitter 202, the SAW filter 124-2 of the receiver 204, and the amplifier 212 of the receiver 204.

During transmission, the transmitter 202 generates a RF transmit signal 218, which is transmitted using the antenna 122-1. To generate the RF transmit signal 218, the DAC 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a RF signal and include some spurious (e.g., unwanted) frequencies, such as a harmonic frequency. The amplifier 210 amplifies the pre-filter transmit signal 224 and passes the amplified pre-filter transmit signal 224 to the first SAW filter 124-1.

The first SAW filter 124-1 filters the amplified pre-filter transmit signal 224 to generate a filtered transmit signal 226. As part of the filtering process, the first SAW filter 124-1 attenuates the one or more spurious frequencies within the pre-filter transmit signal 224. The transmitter 202 provides the filtered transmit signal 226 to the antenna 122-1 for transmission. The transmitted filtered transmit signal 226 is represented by the RF transmit signal 218.

During reception, the antenna 122-2 receives a RF receive signal 228 and passes the RF receive signal 228 to the receiver 204. The second SAW filter 124-2 accepts the received RF receive signal 228, which is represented by a pre-filter receive signal 230. The second SAW filter 124-2 filters any spurious frequencies within the pre-filter receive signal 230 to generate a filtered receive signal 232. Example spurious frequencies can include jammers or noise from the external environment.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The ADC 214 converts the downconverted receive signal 234 into a digital signal, which can be processed by the application processor 108 or another processor associated with the wireless transceiver 120 (e.g., the modem).

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which SAW filters 124 may be included. For example, the SAW filters 124 can be integrated within duplexers or diplexers of the wireless transceiver 120.

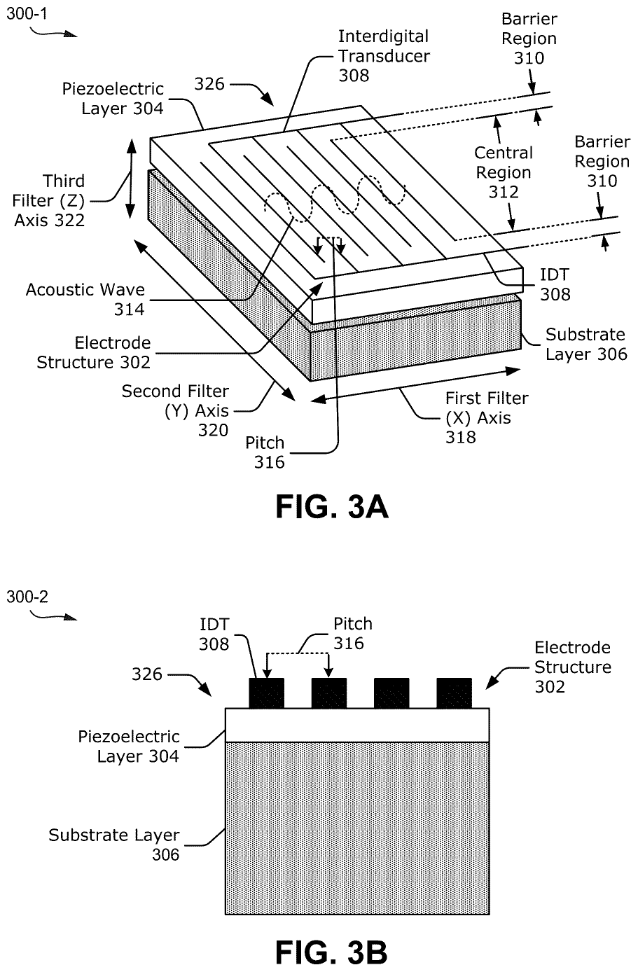

FIG. 3A and FIG. 3B illustrate an example implementation of a TF-SAW filter 326. A three-dimensional perspective view 300-1 of the TF-SAW filter 326 is shown in FIG. 3A, and a two-dimensional (2D) cross section view 300-2 of the TF-SAW filter 326 is shown at in FIG. 3B. In some cases, the TF-SAW filter 326 can correspond to the TF-SAW filter 126 of FIG. 1.

The TF-SAW filter 326 includes at least one electrode structure 302, at least one piezoelectric layer 304 (e.g., piezoelectric material), and at least one substrate layer 306. The electrode structure 302 is implemented using conductive material, such as metal, and can include one or more layers. The one or more layers can include one or more metal layers and can optionally include one or more adhesion layers. As an example, the metal layers can be composed of aluminum (Al), copper (Cu), silver (Ag), gold (Au), tungsten (W), or some combination or doped version thereof. The adhesion layers can be composed of chromium (Cr), titanium (Ti), molybdenum (Mo), Platinum (Pt), or some combination thereof.

The electrode structure 302 can include one or more interdigitated transducers (IDTs) 308. The IDT 308 converts an electrical signal into an acoustic wave and converts the acoustic wave into a filtered electrical signal. Although not explicitly shown, the electrode structure 302 can also include two or more reflectors. In an example implementation, the IDT 308 is arranged between two reflectors (not shown), which reflect the acoustic wave back towards the IDT 308.

In the depicted configuration shown in the 2D cross section view 300-2, the piezoelectric layer 304 is disposed between the electrode structure 302 and the substrate layer 306. The piezoelectric layer 304 can be implemented using a variety of different materials that exhibit piezoelectric properties (e.g., can transfer mechanical energy into electrical energy or electrical energy into mechanical energy). Example types of material include lithium niobate (LN), lithium tantalate (LT), or quartz. In general, the material that forms the piezoelectric layer 304 has a crystalline structure. This crystalline structure is defined by an ordered arrangement of particles (e.g., atoms, ions, or molecules).

The substrate layer 306 includes one or more sublayers that can support passivation, temperature compensation, power handling, mode suppression, and so forth. As an example, the substrate layer 306 can include at least one compensation layer, at least one charge-trapping layer, at least one support layer, or some combination thereof. These sublayers can be considered part of the substrate layer 306 or their own separate layers. Example types of material that can form one or more sublayers within the substrate layer 306 include silicon dioxide (SiO₂)—such as for the compensation layer, polysilicon (poly-Si) (e.g., polycrystalline silicon or multicrystalline silicon such as for the trap rich or charge-trapping layer), amorphous silicon, silicon nitride (SiN), silicon oxynitride (SiON), aluminums nitride (AlN), non-conducting material (e.g., silicon (Si), doped silicon, sapphire, silicon carbide (SiC), fused silica, glass, diamond—such as for a base substrate layer), or some combination thereof.

In some implementations, the substrate layer 306 may be optionally omitted. For example, a thick piezoelectric layer 304 may act as the substrate layer 306 for the SAW filter 326.

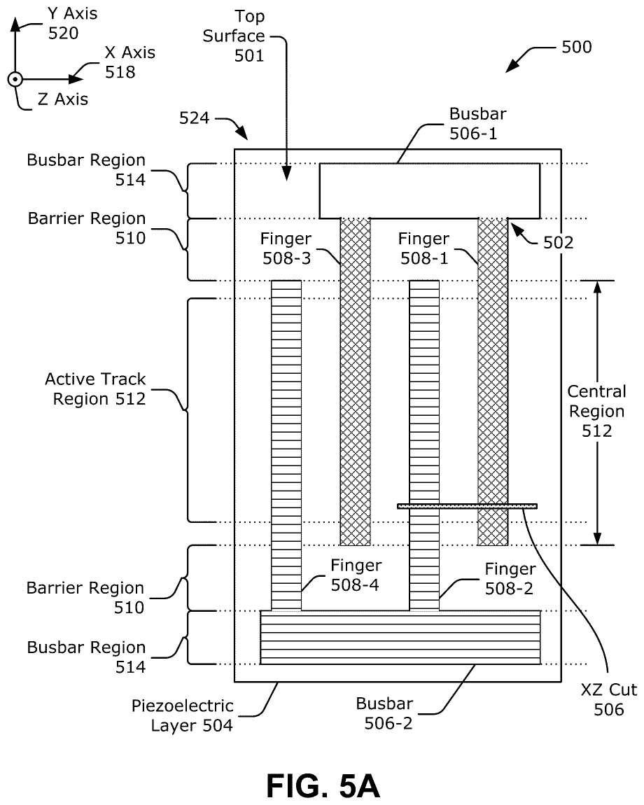

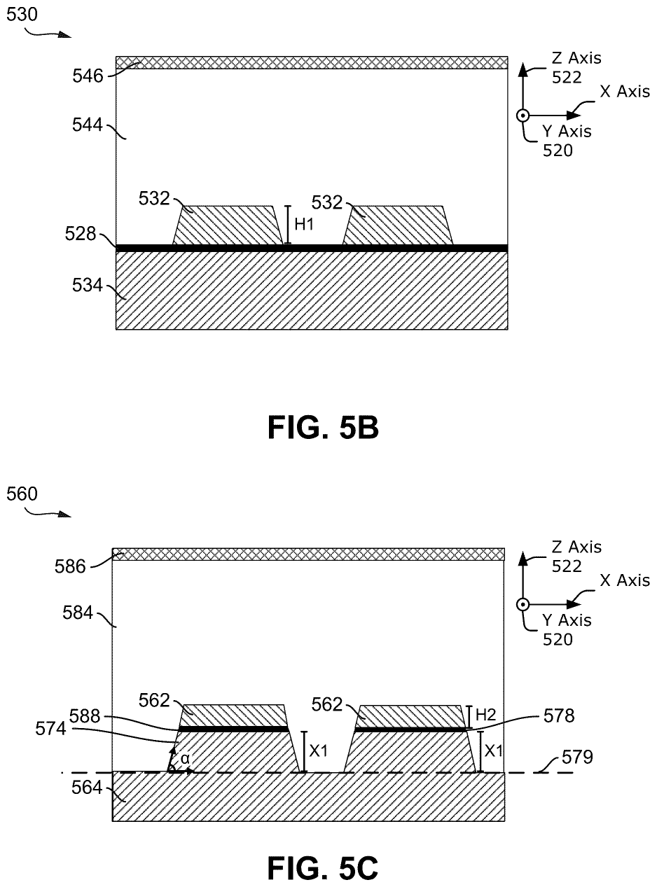

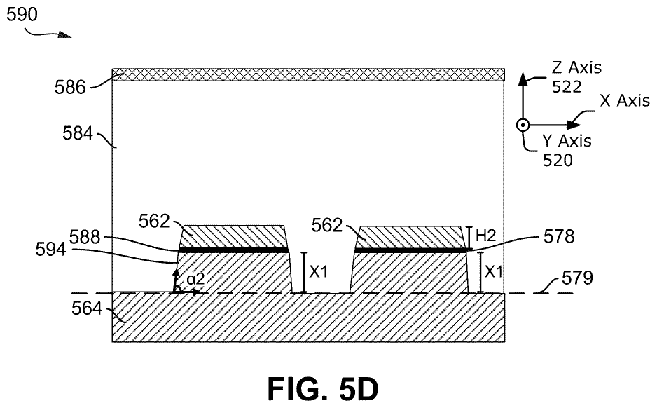

In some implementations, a dielectric underlayer (e.g., dielectric underlayer 528 of FIG. 5B) may be disposed between the electrode structure 302 and the piezoelectric layer 304.

In the three-dimensional perspective view 300-1, the IDT 308 is shown to have two comb-shaped electrode structures with fingers (e.g., electrode fingers) extending from two busbars (e.g., conductive segments or rails) towards each other in an interleaved fashion (e.g., interleaved electrode fingers. The fingers are arranged in an interlocking or interleaved manner in between the two busbars of the IDT 308 (e.g., arranged in an interdigitated manner). In other words, the fingers connected to a first busbar extend towards a second busbar but do not connect to the second busbar. As such, there is a barrier region 310 between the ends of these fingers and the second busbar. Likewise, fingers connected to the second busbar extend towards the first busbar but do not connect to the first busbar. There is therefore a barrier region 310 between the ends of these fingers and the first busbar.

In the direction along the busbars, there is an overlap region including a central region 312 where a portion of one finger overlaps with a portion of an adjacent finger. This central region 312, including the overlap, may be referred to as the aperture, track, or active region where electric fields are produced between fingers to cause an acoustic wave 314 to form at least in this region of the piezoelectric layer 304.

A physical periodicity of the fingers is referred to as a pitch 316 of the IDT 308. The pitch 316 may be indicated in various ways. For example, in certain aspects, the pitch 316 may correspond to a magnitude of a distance between consecutive fingers of the IDT 308 in the central region 312. This distance may be defined, for example, as the distance between center points of each of the fingers. The distance may be generally measured between a right (or left) edge of one finger and the right (or left) edge of an adjacent finger when the fingers have uniform widths. In certain aspects, an average of distances between adjacent fingers of the IDT 308 may be used for the pitch 316. The frequency at which the piezoelectric layer 304 vibrates is a main-resonance frequency of the electrode structure 302. The frequency is determined at least in part by the pitch 316 of the IDT 308 and other properties of the TF-SAW filter 326.

Although not shown, each reflector within the electrode structure 302 can have two busbars and a grating structure of conductive fingers that each connect to both busbars. In some implementations, the pitch of the reflector can be similar to or the same as the pitch 316 of the IDT 308 to reflect the acoustic wave 314 in the resonant frequency range.

In some cases, although not illustrated as such in FIG. 3A and FIG. 3B, a resonator can include multiple components—e.g., in addition to an IDT 308 with multiple fingers. For example, a resonator can include an IDT 308 and at least one reflector (not shown), such as a pair of reflectors. In one illustrative example, the IDT 308 can be coupled together with the IDT 308 between a first reflector and a second reflector (e.g., coupled together as follows: Reflector1+IDT+Reflector2) to form a resonator. In some cases, multiple resonators can be connected together (e.g., in a ladder network, a double-mode surface acoustic wave (SAW) (DMS) filter, or otherwise) to form a filter

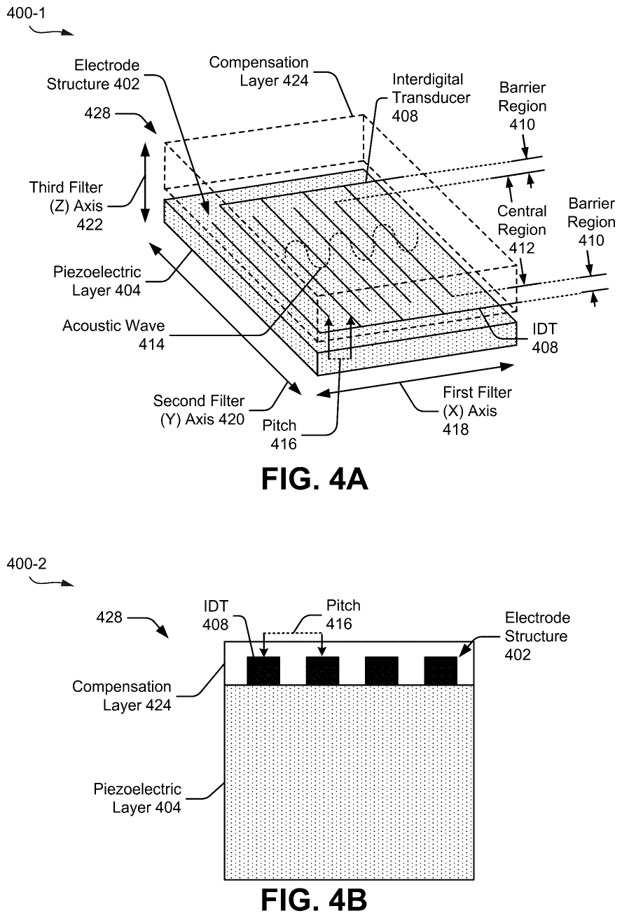

It should be appreciated that while a certain number of fingers are illustrated in FIG. 3A, FIG. 3B, FIG. 4A, FIG. 4B, and FIG. 5A, the number of actual fingers and lengths and width of the fingers and busbars may be different in an actual implementation. Such parameters depend on the particular application and desired filter characteristics. In addition, the TF-SAW filter 326 can include multiple interconnected electrode structures each including multiple IDTs 308 to achieve a desired passband (e.g., multiple interconnected resonators or IDTs 308 in series or parallel connections to form a desired filter transfer function).

In the three-dimensional perspective view 300-1, the TF-SAW filter 326 is defined by a x-axis 318, a y-axis 320, and a z-axis 322. The x-axis 318 and the y-axis 320 are parallel to a planar surface of the piezoelectric layer 304, and the y-axis 320 is perpendicular to the x-axis 318. The z-axis 322 is normal (e.g., perpendicular) to the planar surface of the piezoelectric layer 304. The busbars of the IDT 308 are oriented to be parallel to the x-axis 318. The fingers of the IDT 308 are orientated to be parallel to the y-axis 320. Also, an orientation of the piezoelectric layer 304 causes an acoustic wave 314 to mainly form in a direction of the x-axis 318. As such, the acoustic wave 314 forms in a direction that is substantially perpendicular to the direction of the fingers of the IDT 308.

FIG. 4A and FIG. 4B illustrates an example implementation of the TC-SAW filter 428. A three-dimensional perspective view 400-1 of the TC-SAW filter 428 is shown in FIG. 4A, and a 2D cross section view 400-2 of the TC-SAW filter 428 is shown in FIG. 4B. In some cases, the TC-SAW filter 428 can correspond to the TC-SAW filter 128 of FIG. 1.

The TC-SAW filter 428 includes at least one electrode structure 402, at least one piezoelectric layer 404, and at least one optional compensation layer 424. In some implementations, the compensation layer 424 can provide temperature compensation to enable the TC-SAW filter 428 to achieve a target temperature coefficient of frequency. In example implementations, the compensation layer 424 can be implemented using at least one silicon dioxide layer. In some implementations, a SAW filter may be formed without the inclusion of the optional compensation layer 424.

In the depicted configuration shown in the 2D cross section view 400-2, the electrode structure 402 is disposed between the piezoelectric layer 404 and the compensation layer 424. The piezoelectric layer 404 can form a substrate of the TC-SAW filter 428. In some implementations, a dielectric underlayer (e.g., dielectric underlayer 528 of FIG. 5B) may be disposed between the electrode structure 302 and the piezoelectric layer 304.

The electrode structure 402 of the TC-SAW filter 428 can be similar to the electrode structure 302 described above with respect to the TF-SAW filter 326 of FIG. 3A. Likewise, the piezoelectric layer 404 of the TC-SAW filter 428 can be similar to the piezoelectric layer 304 described above with respect to the TF-SAW filter 326 of FIG. 3A. In some implementations, the piezoelectric layer 404 of the TC-SAW filter 428 can be thicker than the piezoelectric layer 304 of the TF-SAW filter 326 of FIG. 3A and FIG. 3B.

In the three-dimensional perspective view 400-1, the TC-SAW filter 428 is defined by the x-axis 418, the y-axis 420, and the z-axis 422. The x-axis 418 and the y-axis 420 are parallel to a planar surface of the piezoelectric layer 404, and the y-axis 420 is perpendicular to the x-axis 418. The z-axis 422 is normal (e.g., perpendicular) to the planar surface of the piezoelectric layer 404. The busbars of the IDT 408 are oriented to be parallel to the x-axis 418. The fingers of the IDT 408 are orientated to be parallel to the y-axis 420. The physical periodicity of the fingers of the IDT 408 is indicated by pitch 416. Also, an orientation of the piezoelectric layer 404 causes an acoustic wave 414 to mainly form in a direction of the x-axis 418. As such, the acoustic wave 414 forms in a direction that is substantially perpendicular to the direction of the fingers of the IDT 408. Similar to the TF-SAW filter 326 of FIG. 3A and FIG. 3B, the TC-SAW filter 428 of FIG. 4A and FIG. 4B can also include the barrier region 410 and the central region 412.

An example SAW filter (e.g., SAW filter 124 of FIG. 1, SAW filter 124-1 of FIG. 2, SAW filter 124-2 of FIG. 2) accepts a RF signal, such as the pre-filter transmit signal 224 or the pre-filter receive signal 230 shown in FIG. 2. In some cases, the SAW filter can correspond to the TF-SAW filter 326 or the TC-SAW filter 428 of FIG. 4A. For the purposes of illustration, operation of the TC-SAW filter 428 of FIG. 4A and FIG. 4B will be described below. The TF-SAW filter 326 can have similar operations to the TC-SAW filter 428.

Referring to FIG. 4A, the electrode structure 402 excites an acoustic wave 414 on the piezoelectric layer 404 using the inverse piezoelectric effect. For example, the IDT 408 in the electrode structure 402 generates an alternating electric field based on the accepted RF signal. The piezoelectric layer 404 enables the acoustic wave 414 to be formed in response to the alternating electric field generated by the IDT 408. In other words, the piezoelectric layer 404 causes, at least partially, the acoustic wave 414 to form responsive to electrical stimulation by one or more IDTs 408.

The acoustic wave 414 propagates across the piezoelectric layer 404 and interacts with the IDT 408 or another IDT within the electrode structure 402 (not shown). The acoustic wave 414 that propagates can be a standing wave. In some implementations, two reflectors within the electrode structure 402 cause the acoustic wave 414 to be formed as a standing wave across a portion of the piezoelectric layer 404. In other implementations, the acoustic wave 414 propagates across the piezoelectric layer 404 from the IDT 408 to another IDT (not shown).

Using the piezoelectric effect, the electrode structure 402 generates a filtered RF signal based on the propagated surface acoustic wave 414. In particular, the piezoelectric layer 404 generates an alternating electric field due to the mechanical stress generated by the propagation of the acoustic wave 414. The alternating electric field induces an alternating current in the IDT 408 and/or another IDT (not shown). This alternating current forms the filtered RF signal, which is provided at an output of the SAW filter (e.g., SAW filter 124 of FIG. 1, SAW filter 124-1 of FIG. 2, SAW filter 124-2 of FIG. 2). The filtered RF signal can include the filtered transmit signal 226 or the filtered receive signal 232 of FIG. 2.

FIG. 5A illustrates aspects of a SAW filter 524. In some cases, the SAW filter 524 can be similar to and perform similar functions to the SAW filter 124 of FIG. 1. FIG. 5A illustrates a 2D top-down view 500 of the SAW filter 524. Further, as illustrated, the SAW filter 524 includes a top surface 501 of the piezoelectric layer, which can be covered by a compensation layer (e.g., compensation layer 424 of FIG. 4A and FIG. 4B), a dielectric layer, an SiO₂ layer, a passivation layer, and/or any combination thereof. In the depicted configuration, the electrode structure 502 has a comb shape. In some examples, the electrode structure 502 can be similar to and perform similar functions to the electrode structure 302 of FIG. 3A and FIG. 3B, and/or the electrode structure 402 of FIG. 4A and FIG. 4B. Due to the comb shape of the electrode structure 502, the fingers 508-1 to 508-4 are distributed across the x-axis 518 and have lengths along y-axis 520. This distribution causes consecutive pairs of fingers 508-1 to 508-4 to be separated across the x-axis 518. This separation forms gaps (e.g., openings) within the electrode structure 502. Within the central region 512 of FIG. 5A, there are gaps between fingers 508-1 and 508-2, between fingers 508-2 and 508-3, and between fingers 508-3 and 508-4. The electrode structure 502 can also be considered to have gaps to the left of the finger 508-4 (as depicted in FIG. 5A) and to the right of the finger 508-1. The electrode structure 502 can further be considered to have gaps within the barrier region 510 and across portions of the busbar region 514 that are not occupied by the busbars 506-1 and 506-2.

FIG. 5B provides a 2D cross section 530 that can correspond to the XZ profile section 506 of FIG. 5A without raised electrodes. In the example of FIG. 5B, the cross-section includes electrodes 532, a piezoelectric layer 534, a compensation layer 544, a passivation layer 546, and an optional dielectric underlayer 528. In some implementations, the electrodes 532 can correspond to the fingers 508-1 and 508-2 of the electrode structure 502 of FIG. 5A. In the illustrative example of FIG. 5B, the electrodes 532 can have a height H1 above the surface of the dielectric underlayer 528. In some cases, the electrodes 532 can be disposed between an optional compensation layer 544 (e.g., compensation layer 424 of FIG. 4A) and the piezoelectric layer 534. In some implementations, a passivation layer 546 can be disposed above the optional compensation layer 544.

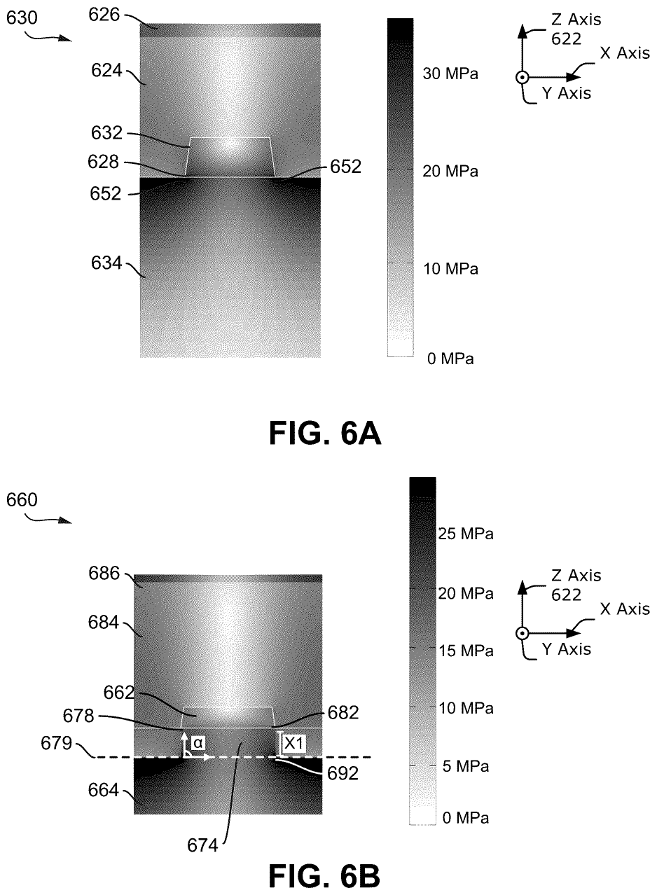

FIG. 6A illustrates an example plot of mechanical stress for a 2D cross section 630 of an electrode included in a piezoelectric device without raised electrodes. In the example of FIG. 6A, an electrode 632 (e.g., electrode structure 502 of FIG. 5A) is disposed on a piezoelectric layer 634 (e.g., piezoelectric layer 504 of FIG. 5A) with an adhesion layer 628 (e.g., a Cr layer) disposed between the electrode 632 and the piezoelectric layer 634. As illustrated, the electrode 632 is disposed between a compensation layer 624 (e.g., compensation layer 544 of FIG. 5B) and the piezoelectric layer 634. In some cases, a passivation layer 626 (e.g., passivation layer 546 of FIG. 5B) can be disposed above the compensation layer 624.

In the illustrated example of FIG. 6A, a white shaded region of the 2D cross section 630 can represent zero mechanical stress. In contrast, a black shade can indicate a maximum mechanical stress, which is equal to approximately 36 megapascal (MPa). In the example of FIG. 6A, maximum stress regions 652 can be found at opposite ends (e.g., along the x-axis) of the junction between the piezoelectric layer 634 and the electrode 632. As further illustrated in FIG. 6A, high levels of mechanical stress may also extend into the dielectric layer 628 and the electrode 632. In some cases, prolonged exposure of the electrode 632 to mechanical stress may eventually exceed the power durability of a piezoelectric device, which may lead to diminishing performance and/or failure of the electrode 632. In one illustrative example, deformities in the electrodes of a SAW filter can result in unwanted frequency shifts in the filter pass band and/or eventual failure.

FIG. 5C provides an additional 2D cross section 560 that can correspond to the XZ profile section 506 of FIG. 5A with raised electrodes. In the example of FIG. 5C, the cross-section includes electrodes 562, a piezoelectric layer 564, piezoelectric structures 574, a compensation layer 584, a passivation layer 586, and an optional dielectric underlayer 588. In some implementations, the electrodes 562 can correspond to the fingers 508-1 and 508-2 of the electrode structure 502 of FIG. 5A. As illustrated in FIG. 5C, a surface of the piezoelectric layer 564 can extend along a surface plane 579. In the example of FIG. 5C, the electrodes 562 are disposed on the piezoelectric structures 574 extending from the piezoelectric layer 564 in the z-axis direction 522. In some cases, the piezoelectric structures 574 can have a height X1 extending above (e.g., in the z-axis direction 522) the surface of the piezoelectric layer 564. In some cases, the piezoelectric structures 574 can be referred to as columns, pillars, protrusions, or the like. In some cases, the height X1 can be at least 80 nanometer (nm). An internal angle α formed between a sidewall of a piezoelectric structure 574 and the surface plane 579 can be between forty-five degrees (45°) and ninety degrees (90°). In some examples, a piezoelectric structure 574 (e.g., a pillar) can extend along a full length of a finger (e.g., fingers 508-1 and 508-3 of the electrode structure 502 of FIG. 5A as indicated by a cross hatch pattern) along the y-axis 520. In some examples, the busbar region (e.g., busbar 506-1 of FIG. 5A) may include electrodes formed at the surface plane 579 (e.g., similar to electrodes 532 of FIG. 5B). However, in some cases, piezoelectric structures 574 can extend along the full length of a finger (e.g., fingers 508-2 and 508-4 of FIG. 5A) as well as extending to a corresponding busbar region (e.g., busbar 506-2 of FIG. 5A) as indicated by the horizontal stripe pattern shown in FIG. 5A.

In some cases, a channel may be formed between the piezoelectric structures 574. In some examples, the depth of the channel can be equal to the height X1. In some cases, the piezoelectric structures 574 can be formed by removing portions of the piezoelectric layer 564 outside of the regions where the electrodes 562 are formed. In some cases, the electrodes 562 may act as a barrier preventing removal of the piezoelectric material that forms the piezoelectric structures 574. In some implementations, a process for removing piezoelectric material from the piezoelectric layer 564 to form the piezoelectric structures 574 may also remove a portion of the electrodes 562. In the illustrated example of FIG. 5C, a height H2 of the electrodes 562 may be less than or equal to a corresponding height of a corresponding electrode 532 of FIG. 5B.

In some cases, introduction of the piezoelectric structures 574 into the layer stack may change the performance of a device (e.g., a TC-SAW filter) incorporating the piezoelectric structures 574. In one illustrative example, the piezoelectric structures 574 may result in a reduction of PZD and/or k² of a TC-SAW filter. In some aspects, the piezoelectric structures 574 may improve TCF for a TC-SAW filter. In some implementations, the piezoelectric structures 574 may reduce mechanical stress in a TC-SAW filter.

FIG. 5D illustrates a second additional 2D cross section 590 that can correspond to the XZ profile section 506 of FIG. 5A with raised electrodes. In the example of FIG. 5D, the cross-section includes electrodes 562, a piezoelectric layer 564, a compensation layer 584, a passivation layer 586, and an optional dielectric underlayer 588 that are similar to and can perform similar functions to like-numbered components of FIG. 5C. However, in the example of FIG. 5D, the angle α2 formed between a sidewall of a piezoelectric structure 594 and the surface plane 579 can be greater (e.g., closer to ninety degrees (90°)) than the angle α between the surface plane 579 and piezoelectric structure 574 of FIG. 5C.

FIG. 6B illustrates an example plot of mechanical stress for a 2D cross section 660 of an electrode included in a piezoelectric device with raised electrodes. In the example of FIG. 6B, an electrode 662 (e.g., electrodes 562 of FIG. 5C) is disposed on a piezoelectric structure 674 (e.g., piezoelectric structure 574 of FIG. 5C) extending from piezoelectric layer 664 (e.g., piezoelectric layer 564 of FIG. 5C) in the z-axis direction 622. As shown in FIG. 6B, the piezoelectric structure 674 can have a height X1 above the surface of the piezoelectric layer 664. As shown in FIG. 6B, a surface of the piezoelectric layer 664 can extend along a surface plane 679. As illustrated in FIG. 6B, the surface plane 679 is parallel to an x-axis y-axis plane. In some examples, an internal angle formed between a sidewall of the piezoelectric structure 674 and the surface plane 679 can be between forty-five degrees (45°) and ninety degrees (90°).

In the example of FIG. 6B, a dielectric layer 678 (e.g., dielectric underlayer 578 of FIG. 5C) can be disposed between the electrode 662 and the piezoelectric structure 674. In some cases, the electrode 662 can be disposed between a compensation layer 684 (e.g., compensation layer 584 of FIG. 5C) and the piezoelectric layer 664. In some cases, a passivation layer 686 (e.g., passivation layer 586 of FIG. 5C) can be disposed above the compensation layer 684.

In the illustrated example of FIG. 6B, a white shaded region of the 2D cross section 660 can represent zero mechanical stress. In contrast, a black shade can indicate a maximum mechanical stress, which is equal to approximately 29 megapascal (MPa). In the example of FIG. 6B, maximum stress regions 692 can be found at the junctions between surface of the piezoelectric layer 664 and the piezoelectric structure 674. As further illustrated in FIG. 6B, high levels of mechanical stress may also extend into the piezoelectric structure 674. As illustrated, the maximum mechanical stress within the electrode 662 may be approximately half of the maximum mechanical stress within the electrode 632 as shown in FIG. 6A. In some cases, the reduction of mechanical stress induced in the electrode 662 (e.g., at a junction 682 between the piezoelectric structure 674 and the electrode 662) by the addition of the piezoelectric structure 674 may increase the power durability of a piezoelectric device.

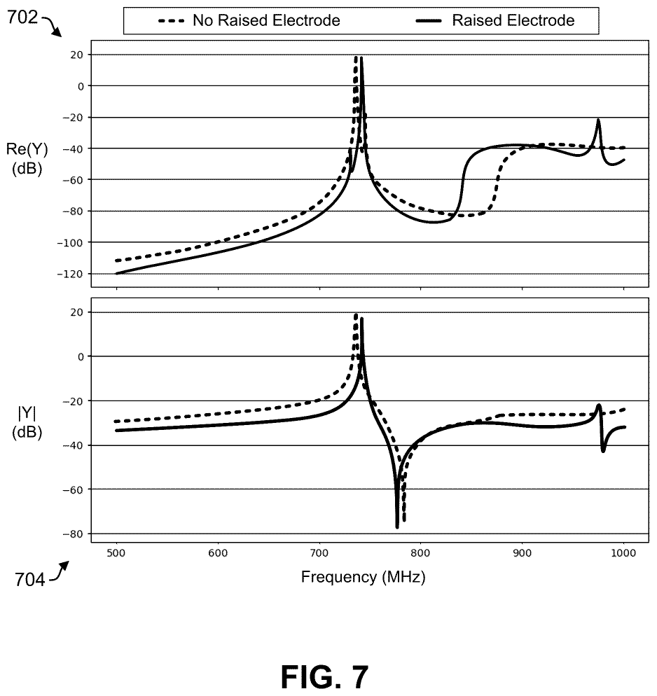

FIG. 7 illustrates plots of simulated performance of TC-SAW filters without raised electrodes and with raised electrodes. In the plots of FIG. 7, the dashed lines can correspond to simulated performance of a TC-SAW filter without raised electrodes (e.g., as shown in FIG. 5B) and the solid lines can correspond to simulated performance of a TC-SAW filter with raised electrodes (e.g., as shown in FIG. 5C). In the example of FIG. 7, the curves in the upper plot 702 can represent the real part of admittance Re(Y) over frequency for simulated TC-SAW devices. In contrast, the curves in the lower plot 704 can represent the absolute value of admittance |Y|over frequency for simulated TC-SAW devices.

As shown in the plots 702, 704 of FIG. 7, a TC-SAW filter with raised electrodes can produce comparable admittance characteristics to a TC-SAW filter without raised electrodes. In some aspects, in cases where the PZD and/or k² of a TC-SAW filter without raised electrodes exceeds requirements to attain a desired admittance, the potential loss of PZD and/or k² that can result from the inclusion of piezoelectric structures (e.g., piezoelectric structures 574 of FIG. 5C) may still allow for attaining the desired admittance while gaining benefits of improved TCF and/or increased power durability associated with inclusion of the piezoelectric structures.

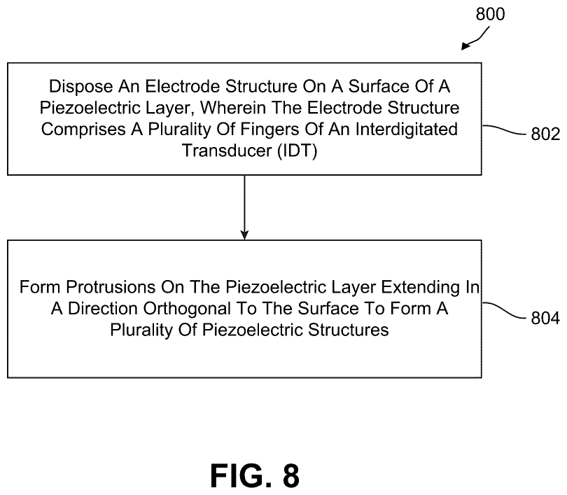

FIG. 8 is a flow diagram of a process 800. The process 800 may be performed by a computing device (or apparatus) or a component (e.g., a chipset, codec, etc.) of the computing device. The computing device may be a mobile device, a network-connected wearable such as a watch, an XR device such as a VR device or AR device, a vehicle or component or system of a vehicle, a network node/entity/device, wireless device, or other type of computing device. The operations of the process 800 may be implemented as software components that are executed and run on one or more processors.

At block 802, the computing device (or component thereof) may dispose an electrode structure on a surface plane of a piezoelectric layer, wherein the electrode structure comprises a plurality of fingers of an interdigitated transducer (IDT).

At block 804, the computing device (or component thereof) may form protrusions on the piezoelectric layer extending in a direction orthogonal to the surface plane to form a plurality of piezoelectric structures. In some examples, forming the protrusions on the piezoelectric layer comprises removing the portions of the piezoelectric layer. In some implementations, forming the protrusions on the piezoelectric layer comprises attaching an additional piezoelectric layer to the surface plane of the piezoelectric layer. In some cases, forming the protrustions on the piezoelectric layer produces a plurality of channels between parallel piezoelectric channels. In some cases, a minimum depth of the plurality of channels is at least 80 nanometer (nm).

In some implementations, one or more piezoelectric structures of the plurality of piezoelectric structures extend along a length of corresponding fingers of the plurality of fingers of the IDT.

In some aspects, a first piezoelectric structure of the plurality of piezoelectric structures comprises a first sidewall and second sidewall extending in the direction orthogonal to the surface plane. In some examples, a first external angle formed between the first sidewall and the surface plane is between forty-five degrees (45°) and ninety degrees (90°) and a second external angle formed between the second sidewall and the surface plane is between forty-five degrees (45°) and ninety degrees (90°).

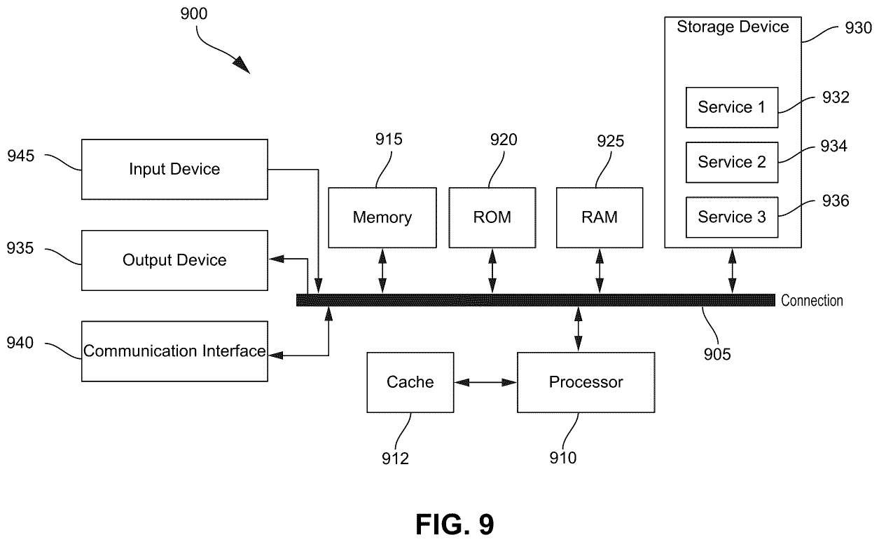

FIG. 9 is a diagram illustrating an example of a system for implementing certain aspects of the present technology. In particular, FIG. 9 illustrates an example of computing system 900 which can include MEMS transducers or devices including MEMS devices implemented using piezoelectric structures (e.g., columns, pillars, protrusions, or the like) and raised electrodes in accordance with aspects described herein. An acoustic transducer can be integrated, for example, with any computing device making up internal computing system, a remote computing system, a camera, or any component thereof in which the components of the system are in communication with each other using connection 905. Connection 905 may be a physical connection using a bus, or a direct connection into processor 910, such as in a chipset architecture. Connection 905 may also be a virtual connection, networked connection, or logical connection.

Example system 900 includes at least one processing unit (CPU or processor) 910 and connection 905 that communicatively couples various system components including system memory 915, such as read-only memory (ROM) 920 and random access memory (RAM) 925 to processor 910. Computing system 900 may include a cache 912 of high-speed memory connected directly with, in close proximity to, or integrated as part of processor 910.

Processor 910 may include any general purpose processor and a hardware service or software service, such as services 932, 934, and 936 stored in storage device 930, configured to control processor 910 as well as a special-purpose processor where software instructions are incorporated into the actual processor design. Processor 910 may essentially be a completely self-contained computing system, containing multiple cores or processors, a bus, memory controller, cache, etc. A multi-core processor may be symmetric or asymmetric.

To enable user interaction, computing system 900 includes an input device 945, which may represent any number of input mechanisms, such as a microphone for speech or audio detection (e.g., PZ MEMS transducer or a MEMS transducer system in accordance with aspects described above, etc.) along with other input devices 945 such as a touch-sensitive screen for gesture or graphical input, keyboard, mouse, motion input, speech, etc. Computing system 900 may also include output device 935, which may be one or more of a number of output mechanisms. In some instances, multimodal systems may enable a user to provide multiple types of input/output to communicate with computing system 900.

Computing system 900 may include communications interface 940, which may generally govern and manage the user input and system output. The communication interface may perform or facilitate receipt and/or transmission wired or wireless communications using wired and/or wireless transducers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a RF identification (RFID) wireless signal transfer, near-field communications (NFC) wireless signal transfer, dedicated short range communication (DSRC) wireless signal transfer, 902.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 940 may also include one or more Global Navigation Satellite System (GNSS) receivers or transducers that are used to determine a location of the computing system 900 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 930 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1 (L1 ) cache, Level 2 (L2 ) cache, Level 3 (L3 ) cache, Level 4 (L4 ) cache, Level 5 (L5 ) cache, or other (L #) cache), resistive random-access memory (RRAM/ReRAM), phase change memory (PCM), spin transfer torque RAM (STT-RAM), another memory chip or cartridge, and/or a combination thereof.

The storage device 930 may include software services, servers, services, etc., that when the code that defines such software is executed by the processor 910, it causes the system to perform a function. In some embodiments, a hardware service that performs a particular function may include the software component stored in a computer-readable medium in connection with the necessary hardware components, such as processor 910, connection 905, output device 935, etc., to carry out the function. The term “computer-readable medium” includes, but is not limited to, portable or non-portable storage devices, optical storage devices, and various other mediums capable of storing, containing, or carrying instructions(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

For clarity of explanation, in some instances the present technology may be presented as including individual functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purpose computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

A number of implementations have been described. Nevertheless, it will be understood that various modifications may be made without departing from the spirit and scope of the disclosure. Other embodiments are within the scope of the claims.

Illustrative aspects of the disclosure include:
Aspect 1: An apparatus, comprising: a piezoelectric layer comprising a surface along a surface plane, wherein a plurality of piezoelectric structures extend from the surface in a direction orthogonal to the surface plane; and an electrode layer comprising an electrode disposed on the plurality of piezoelectric structures, wherein the electrode extends along an axis parallel to the surface plane to form at least one finger of an interdigitated transducer (IDT).
Aspect 2: The apparatus of Aspect 1, wherein a piezoelectric structure of the plurality of piezoelectric structures extends along a length of the finger.
Aspect 3: The apparatus of Aspect 2, further comprising an additional electrode, the additional electrode comprising an additional finger of the IDT, wherein the additional electrode is disposed on an additional piezoelectric structure of the plurality of piezoelectric structures extending from the surface in the direction orthogonal to the surface plane.
Aspect 4: The apparatus of Aspect 3, wherein the piezoelectric layer comprises a channel between the piezoelectric structure and the additional piezoelectric structure.
Aspect 5: The apparatus of Aspect 4, wherein a depth of the channel is at least eighty nanometer (nm).
Aspect 6: The apparatus of Aspect 4, wherein the channel extends along a length of the finger of the IDT in a longest dimension of the finger of the IDT.
Aspect 7: The apparatus of Aspect 2, wherein the piezoelectric structure comprises a first sidewall and second sidewall extending in the direction orthogonal to the surface plane, and wherein a first sidewall height of the first sidewall is at least eighty nanometer (nm) and a second sidewall height of the second sidewall is at least eighty nm.
Aspect 8: The apparatus of Aspect 7, wherein the electrode spans a width of the piezoelectric structure between the first sidewall and the second sidewall.
Aspect 9: The apparatus of Aspect 2, wherein the piezoelectric structure comprises a first sidewall and second sidewall extending in the direction orthogonal to the surface plane, and wherein a first internal angle formed between the first sidewall and the surface plane is between forty-five degrees (45°) and ninety degrees (90°) and a second internal angle formed between the second sidewall and the surface plane is between forty-five degrees (45°) and ninety degrees (90°).
Aspect 10: The apparatus of any one of Aspects 1 to 9, further comprising a dielectric layer disposed between the electrode layer and the piezoelectric layer.
Aspect 11: The apparatus of any one of Aspects 1 to 10, further comprising a compensation layer formed over the piezoelectric layer and the electrode layer.
Aspect 12: The apparatus of Aspect 11, wherein the compensation layer comprises a silicon dioxide (SiO₂) layer.
Aspect 13: The apparatus of any one of Aspects 1 to 12, a surface acoustic wave (SAW) filter comprises the IDT.
Aspect 14: The apparatus of Aspect 13, wherein a transceiver system comprises the SAW filter.
Aspect 15: A method, comprising: disposing an electrode structure on a surface of a piezoelectric layer, wherein the electrode structure comprises a plurality of fingers of an interdigitated transducer (IDT); and forming protrusions on the piezoelectric layer extending in a direction orthogonal to the surface plane to form a plurality of piezoelectric structures.
Aspect 16: The method of Aspect 15, forming the protrusions on the piezoelectric layer comprises removing portions of the piezoelectric layer to form a plurality of channels between parallel piezoelectric structures of the plurality of piezoelectric structures.
Aspect 17: The method of Aspect 16, forming the protrusions on the piezoelectric layer comprises forming a plurality of channels between parallel piezoelectric structures of the plurality of piezoelectric structures, and wherein a minimum depth of the plurality of channels is at least 80 nanometer (nm).
Aspect 18: The method of any one of Aspects 15 to 17, wherein one or more piezoelectric structures of the plurality of piezoelectric structures extend along a length of corresponding fingers of the plurality of fingers of the IDT.
Aspect 19: The method of any one of Aspects 15 to 18, wherein a first piezoelectric structure of the plurality of piezoelectric structures comprises a first sidewall and second sidewall extending in the direction orthogonal to the surface.
Aspect 20: The method of Aspect 19, wherein a first external angle formed between the first sidewall and the surface is between forty-five degrees (45°) and ninety degrees (90°) and a second external angle formed between the second sidewall and the surface is between forty-five degrees (45°) and ninety degrees (90°).
Aspect 21: The method of any one of Aspects 15 to 19, wherein forming the protrusions on the piezoelectric layer comprises attaching an additional piezoelectric layer to the surface plane of the piezoelectric layer
Aspect 22: An apparatus, comprising: a micro-acoustic resonator comprising: a piezoelectric structure having one or more layers and formed from one or more piezoelectric materials, the piezoelectric structure including a plurality of separated protrusions; and an interdigitated electrode structure comprising a conductive material disposed at least in part on or above the plurality of separated protrusions of the piezoelectric structure and comprising a first plurality of electrode fingers extending from a first busbar towards a second busbar and interdigitated with a second plurality of electrode fingers extending from the second busbar towards the first busbar. structures, wherein the electrode extends along an axis parallel to the surface plane to form a finger of an interdigitated transducer (IDT).
Aspect 23: A non-transitory computer-readable storage medium having stored thereon instructions which, when executed by one or more processors, cause the one or more processors to perform any of the operations of aspects 1 to 22.
Aspect 24: An apparatus comprising means for performing any of the operations of aspects 1 to 22.

What is claimed is:

1. An apparatus, comprising:
a piezoelectric layer comprising a surface along a surface plane, wherein a plurality of piezoelectric structures extend from the surface in a direction orthogonal to the surface plane; and
an electrode layer comprising an electrode disposed on the plurality of piezoelectric structures, wherein the electrode extends along an axis parallel to the surface plane to form at least one finger of an interdigitated transducer (IDT).

2. The apparatus of claim 1, wherein a piezoelectric structure of the plurality of piezoelectric structures extends along a length of the at least one finger.

3. The apparatus of claim 2, further comprising an additional electrode, the additional electrode comprising an additional finger of the IDT, wherein the additional electrode is disposed on an additional piezoelectric structure of the plurality of piezoelectric structures extending from the surface in the direction orthogonal to the surface plane.

4. The apparatus of claim 3, wherein the piezoelectric layer comprises a channel between the piezoelectric structure and the additional piezoelectric structure.

5. The apparatus of claim 4, wherein a depth of the channel is at least eighty nanometer (nm).

6. The apparatus of claim 4, wherein the channel extends along a length of the at least one finger of the IDT in a longest dimension of the at least one finger of the IDT.

7. The apparatus of claim 2, wherein the piezoelectric structure comprises a first sidewall and second sidewall extending in the direction orthogonal to the surface plane, and wherein a first sidewall height of the first sidewall is at least eighty nanometer (nm) and a second sidewall height of the second sidewall is at least eighty nm.

8. The apparatus of claim 7, wherein the electrode spans a width of the piezoelectric structure between the first sidewall and the second sidewall.

9. The apparatus of claim 2, wherein the piezoelectric structure comprises a first sidewall and second sidewall extending in the direction orthogonal to the surface plane, and wherein a first internal angle formed between the first sidewall and the surface plane is between forty-five degrees (45°) and ninety degrees (90°) and a second internal angle formed between the second sidewall and the surface plane is between forty-five degrees (45°) and ninety degrees (90°).

10. The apparatus of claim 1, further comprising a dielectric layer disposed between the electrode layer and the piezoelectric layer.

11. The apparatus of claim 1, further comprising a compensation layer formed over the piezoelectric layer and the electrode layer.

12. The apparatus of claim 11, wherein the compensation layer comprises a silicon dioxide (SiO₂) layer.

13. The apparatus of claim 1, further comprising a surface acoustic wave (SAW) filter comprising the piezoelectric layer and the electrode layer.

14. The apparatus of claim 13, further comprising a transceiver system comprising the SAW filter.

15. A method, comprising:
disposing an electrode structure on a surface of a piezoelectric layer, wherein the electrode structure comprises a plurality of fingers of an interdigitated transducer (IDT); and
forming protrusions on the piezoelectric layer extending in a direction orthogonal to the surface to form a plurality of piezoelectric structures.

16. The method of claim 15, wherein forming the protrusions on the piezoelectric layer comprises removing portions of the piezoelectric layer to form a plurality of channels between parallel piezoelectric structures of the plurality of piezoelectric structures.

17. The method of claim 16, wherein forming the protrusions on the piezoelectric layer comprises forming a plurality of channels between parallel piezoelectric structures of the plurality of piezoelectric structures, and wherein a minimum depth of the plurality of channels is at least 80 nanometer (nm).

18. The method of claim 15, wherein one or more piezoelectric structures of the plurality of piezoelectric structures extend along a length of corresponding fingers of the plurality of fingers of the IDT.

19. The method of claim 15, wherein a first piezoelectric structure of the plurality of piezoelectric structures comprises a first sidewall and second sidewall extending in the direction orthogonal to the surface.

20. An apparatus, comprising:
a micro-acoustic resonator comprising:
a piezoelectric structure having one or more layers and formed from one or more piezoelectric materials, the piezoelectric structure including a plurality of separated protrusions, the plurality of separated protrusions extending in a direction orthogonal to a surface plane of the piezoelectric structure; and
an interdigitated electrode structure comprising a conductive material disposed at least in part on or above the plurality of separated protrusions of the piezoelectric structure and comprising a first plurality of electrode fingers extending from a first busbar towards a second busbar and interdigitated with a second plurality of electrode fingers extending from the second busbar towards the first busbar, wherein the first plurality of electrode fingers and the second plurality of electrode fingers extend along an axis parallel to the surface plane to form fingers of an interdigitated transducer (IDT).
